(19) United States
(12) Patent Application Publication
(10) Pub. No.: US 2026/0344269 A1
(43) Pub. Date: Oct. 29, 2026

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., Ltd., Yongin-si (KR)

(72) Inventors: Taesang Park, Yongin-si (KR); TAESUNG KIM, Yongin-si (KR); KYONG-CHOL LEE, Yongin-si (KR); HYUNMIN CHO, Yongin-si (KR)

(21) Appl. No.: 19/656,475

(22) Filed: Apr. 23, 2026

(30) Foreign Application Priority Data
Apr. 28, 2025 (KR) 10-2025-0055239

(51) Int. Cl. H10K 59/80; H10K 59/12

(52) U.S. Cl. CPC H10K 59/879; H10K 59/1201

(57) ABSTRACT

A display device includes: a display panel including a display area, a peripheral area adjacent to the display area, and a pixel which emits light; and a lens layer which is on the display panel and controls the light emitted from the pixel. The lens layer includes a lens substrate positioned across the display area and the peripheral area. The lens layer includes a refractive layer which has a groove pattern in the display area and defines an opening extending toward a surface of the lens substrate in the peripheral area.

### RELATED APPLCATION

This application claims priority to Korean Patent Application No. 10-2025-0055239, filed on Apr. 28, 2025, and all the benefits accruing therefrom under 35 U.S.C. §119, the content of which in its entirety is herein incorporated by reference.

### BACKGROUND

### 1. Field

The present disclosure relates generally to a display device, a method of manufacturing the display device, and an electronic device including the display device. More particularly, the present disclosure relates to a display device utilizing optical path control, a method of manufacturing the display device, and an electronic device including the display device.

### 2. Description of the Related Art

A display device is a device that displays an image to provide visual information to users. Recently, research is being conducted on using a micro lens within the display device to increase the resolution of the image displayed. The micro lens may be manufactured by patterning a high-refractive-index film with an uneven pattern on a substrate.

However, when patterning a high-refractive-index film through etching or direct patterning, problems may arise in which defects occur within the micro lens or in which the shape of the high-refractive-index film is not formed as designed.

### SUMMARY

Embodiments provide a display device that minimizes defects and resolution degradation in a micro lens.

Embodiments provide a method of manufacturing the display device.

Embodiments provide an electronic device including the display device.

A display device according to an embodiment of the present disclosure includes: a display panel including a display area, a peripheral area adjacent to the display area, and a pixel which emits light; and a lens layer which is on the display panel and controls the light emitted from the pixel. The lens layer includes: a lens substrate positioned across the display area and the peripheral area; and a refractive layer which has a groove pattern in the display area and defines an opening extending toward a surface of the lens substrate in the peripheral area.

In an embodiment, the display device may include a metal particle formed on a surface of the refractive layer.

In an embodiment, the metal particle may include at least one of indium or titanium.

In an embodiment, the groove pattern may have a rounded shape in a direction toward the lens substrate in a cross-section.

In an embodiment, the groove pattern may have a rounded shape in a direction away from the lens substrate in a cross-section.

In an embodiment, the lens substrate may be between the refractive layer and the display panel in a cross-section.

In an embodiment, the display device may further include an overcoating layer on the lens substrate.

In an embodiment, the refractive layer may be between the lens substrate and the display panel in a cross-section.

In an embodiment, the display device may further include an adhesive layer which fills the groove pattern of the refractive layer and may be between the display panel and the refractive layer in the cross-section.

In an embodiment, the lens substrate may include a photosensitive polyimide.

A method of manufacturing a display device according to an embodiment of the present disclosure includes: forming a first preliminary refractive layer on a lens substrate, wherein the lens substrate includes a first area and a second area adjacent to the first area; forming a second preliminary refractive layer which has a groove pattern in the first area and defines an opening extending toward a surface of the lens substrate in the second area by removing a portion of the first preliminary refractive layer; forming a fixing film on the second preliminary refractive layer in the first area and the second area; curing the second preliminary refractive layer; forming a refractive layer by removing the fixing film in the first area and the second area; and bonding the lens substrate and the refractive layer to a display panel.

In an embodiment, forming the second preliminary refractive layer may include: providing a mask including a light blocking portion, a transmission portion, and a semi-transmission portion which has a transmittance greater than a transmittance of the light blocking portion and smaller than a transmittance of the transmission portion; forming the opening by removing a first portion of the second preliminary refractive layer corresponding to the transmission portion of the mask; and forming the groove pattern by removing a second portion of the second preliminary refractive layer corresponding to the light blocking portion and the semi-transmission portion of the mask, wherein the second portion is different from the first portion.

In an embodiment, the fixing film may include at least one selected from a group consisting of indium tin oxide (ITO), indium zinc oxide (IZO), indium gallium zinc oxide (IGZO), and titanium.

In an embodiment, in the bonding the lens substrate and the refractive layer to the display panel, the lens substrate and the refractive layer may be bonded to the display panel such that the lens substrate faces the display panel.

In an embodiment, in the bonding the lens substrate and the refractive layer to the display panel, the lens substrate and the refractive layer may be bonded to the display panel such that the refractive layer faces the display panel.

In an embodiment, in the bonding the lens substrate and the refractive layer to the display panel, the display panel may include a display area and a peripheral area adjacent to the display area, the display area of the display panel and the first area of the lens substrate may correspond to each other, and the peripheral area of the display panel and the second area of the lens substrate may correspond to each other.

An electronic device according to an embodiment of the present disclosure includes: a display panel including a display area, a peripheral area adjacent to the display area, and a pixel which emits light; a lens layer which is on the display panel and controls the light emitted from the pixel, wherein the lens layer includes: a lens substrate positioned across the display area and the peripheral area; and a refractive layer which has a groove pattern in the display area and defines an opening extending toward a surface of the lens substrate in the peripheral area; and a processor which transmits an image data signal and an input control signal to the display panel.

In an embodiment, the electronic device further includes a metal particle formed on a surface of the refractive layer.

In an embodiment, the metal particle may include at least one of indium or titanium.

In an embodiment, the lens substrate may include a photosensitive polyimide.

In a display device according to embodiments of the present disclosure, gas may be released during the manufacturing process of a lens layer, and when the gas remains within the lens layer, the gas may weaken the bonding force between a lens substrate and a refractive layer. Accordingly, since an opening formed in the refractive layer in a peripheral area releases the gas, a lifting phenomenon caused by weakening the bonding force between the lens substrate and the refractive layer may be prevented. Accordingly, the durability of the display device including the lens layer may be improved, and the display quality may be improved because a phenomenon of deterioration of the resolution of an image generated by light emitted from a light-emitting element is prevented.

In a method of manufacturing the display device according to embodiments of the present disclosure, since a curing process is performed on a second preliminary refractive layer after a fixing film is formed on the second preliminary refractive layer, the shape of the second preliminary refractive layer may not be deformed, and the fixation of the second preliminary refractive layer may be continuously maintained. Accordingly, the method may be implemented without an additional process for fixing and maintaining the shape of the refractive layer, the process time and the process cost may be reduced.

In an electronic device according to embodiments of the present disclosure, the electronic device may include a display device with improved durability and display quality, a processor, a power module, and other components for operating the display device, such that the electronic device may provide an image to a user while operating stably.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a cross-sectional view illustrating an example of a cross-section of the display device taken along the line I-I’ of FIG. 1.

FIG. 3 is an enlarged cross-sectional view illustrating the area A of FIG. 2.

FIGS. 4, 5, 6, 7, 8, and 9, are views illustrating a method of manufacturing the display device of FIG. 2.

FIG. 10 is a cross-sectional view illustrating another example of a cross-section of the display device taken along the line I-I’ of FIG. 1.

FIG. 11 is a view illustrating a method of manufacturing the display device of FIG. 10.

FIG. 12 is a cross-sectional view illustrating still another example of a cross-section of the display device taken along the line I-I’ of FIG. 1.

FIG. 13 is a block diagram of an electronic device according to an embodiment of the present disclosure.

FIG. 14 is a schematic view illustrating various embodiments of the electronic device of FIG. 13.

### DETAILED DESCRIPTION

Hereinafter, embodiments of the present disclosure will be described in detail with reference to the accompanying drawings. The same reference numerals are used for the same components in the drawings, and redundant descriptions of the same components will be omitted.

Embodiments supported by the present disclosure will now be described more fully hereinafter with reference to the accompanying drawings, in which one or more example embodiments are illustrated. Aspects supported by the present disclosure may, however, be embodied in different forms and should not be construed as limited to the embodiments set forth herein. Rather, these example embodiments are provided so that this disclosure will be thorough and complete, and will fully convey the scope of example aspects of the invention to those skilled in the art.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, comp

The term “substantially,” as used herein, means approximately or actually. The term “substantially equal” means approximately or actually equal. The term “substantially the same” means approximately or actually the same. The term “substantially identical” means approximately or actually identical. The term “substantially perpendicular” means approximately or actually perpendicular.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as "A or B”, "at least one of A and B”, "at least one of A or B”, "A, B, or C”, "at least one of A, B, and C”, and "at least one of A, B, or C”, may include any one of, or all possible combinations of the items enumerated together in a corresponding one of the phrases.

It is to be understood that if an element (e.g., a first element) is referred to, with or without the term "operatively" or "communicatively", as "coupled with”, "coupled to”, "connected with”, or "connected to" another element (e.g., a second element), it means that the element may be coupled with the other element directly (e.g., wiredly), wirelessly, or via a third element.

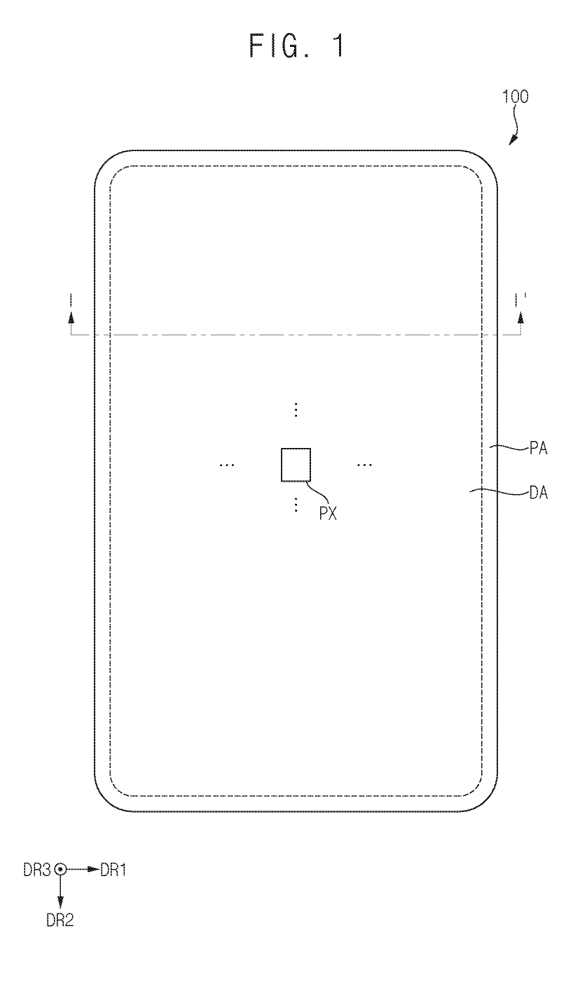

FIG. 1 is a plan view illustrating a display device according to an embodiment of the present disclosure.

Referring to FIG. 1, a display device 100 according to an embodiment of the present disclosure may include a display area DA and a peripheral area PA. The display area DA may be defined as an area in which an image may be displayed by generating light or adjusting the transmittance of light provided from an external light source. The peripheral area PA may be defined as an area in which an image generated by the light is not displayed. However, the peripheral area PA according to embodiments of the present disclosure is not necessarily limited thereto, and an image may be displayed in a portion of the peripheral area PA. The peripheral area PA may be adjacent to the display area DA.

In this specification, a plane may be defined by a first direction DR1 and a second direction DR2 intersecting the first direction DR1. For example, the second direction DR2 may be perpendicular to the third direction DR1. In some aspects, a third direction DR3 may be perpendicular to the plane.

At least one pixel PX that emits light may be disposed in the display area DA. A plurality of pixels PX may be arranged in the display area DA. For example, the pixel PX may be arranged in the first direction DR1 and the second direction DR2 in a matrix form in the display area DA. The pixels PX may include sub-pixels that emit light of different colors. For example, the sub-pixels may include first to third sub-pixels, the first sub-pixel may emit a first light, the second sub-pixel may emit a second light, and the third sub-pixel may emit a third light. In an embodiment, the first light may be red, the second light may be green, and the third light may be blue. However, the color of light emitted by each of the sub-pixels included in the pixel PX according to embodiments of the present disclosure is not limited thereto, and may emit light having various colors such as magenta, cyan, yellow, and the like.

The peripheral area PA may surround at least a portion of the display area DA. For example, the peripheral area PA may entirely surround the display area DA in a plan view. A driver for driving the pixel PX may be disposed in the peripheral area PA. The driver may provide signals and/or voltages to the pixel PX. For example, the driver may include a data driver, a scan driver, an emission driver, a power voltage generator, a timing controller, and the like.

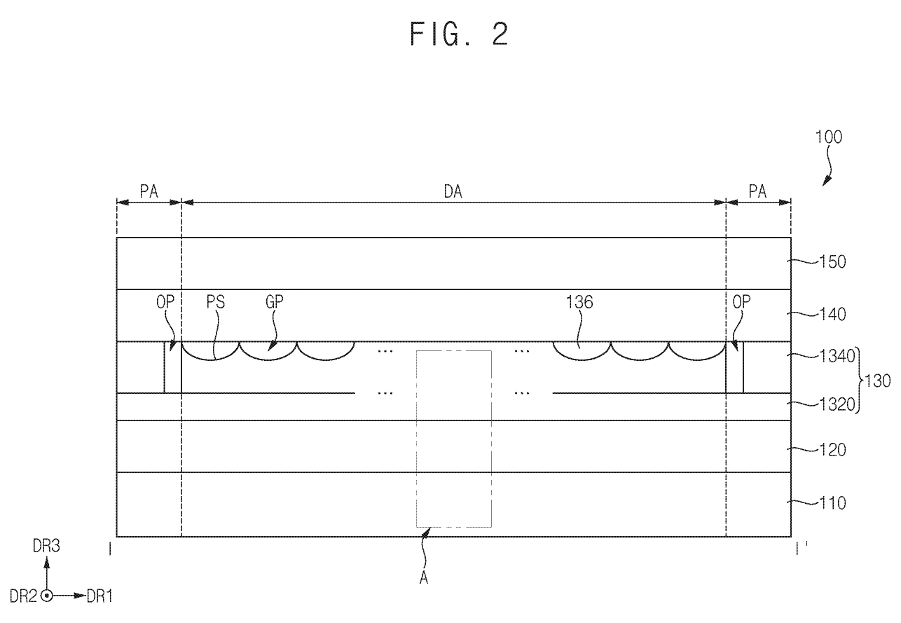

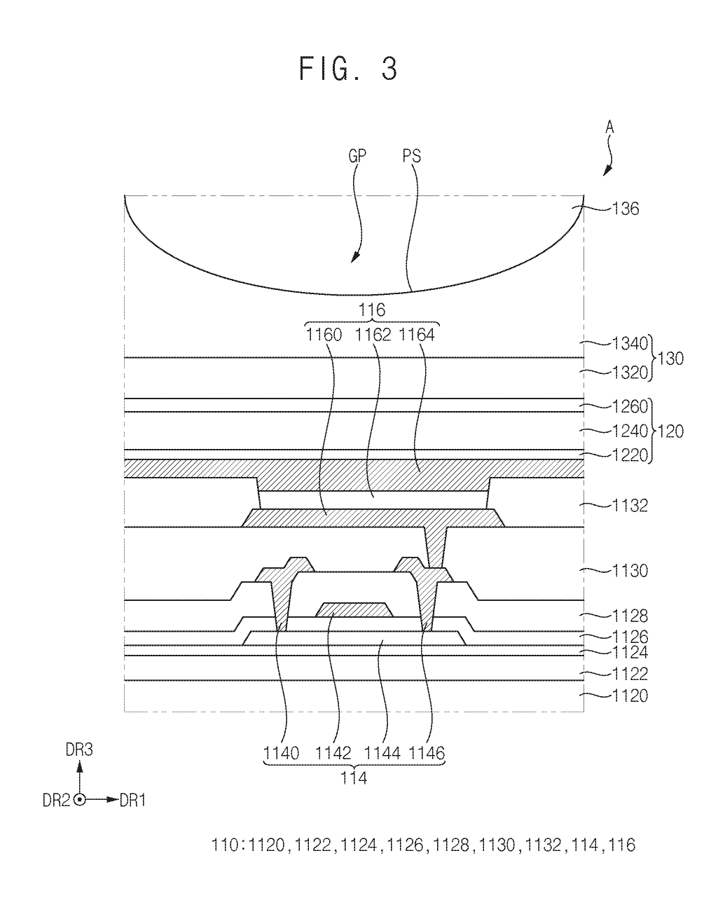

FIG. 2 is a cross-sectional view illustrating an example of a cross-section of the display device taken along the line I-I’ of FIG. 1. FIG. 3 is an enlarged cross-sectional view illustrating the area A of FIG. 2.

Referring to FIGS. 2 and 3, the display device 100 may include a display panel 110, a thin film encapsulation layer 120, a lens layer 130, an overcoating layer 136, an optical functional layer 140, and an encapsulation substrate 150. The display panel 110 may include a base substrate 1120, a first insulating layer 1122, a second insulating layer 1124, a third insulating layer 1126, a fourth insulating layer 1128, a fifth insulating layer 1130, a pixel defining layer 1132, a transistor 114, and a light-emitting element 116. The transistor 114 may include a first electrode 1140, a gate electrode 1142, an active pattern 1144, and a second electrode 1146. The light-emitting element 116 may include a pixel electrode 1160, a light-emitting layer 1162, and a common electrode 1164. The thin film encapsulation layer 120 may include a first encapsulation layer 1220, a second encapsulation layer 1240, and a third encapsulation layer 1260. The lens layer 130 may include a lens substrate 1320 and a refractive layer 1340.

The display panel 110 may include the pixel (PX, refer to FIG. 1) that emits light. For example, the pixel may include the transistor 114 and the light-emitting element 116. Accordingly, the display panel 110 may emit light in response to an applied electrical signal and/or voltage.

The base substrate 1120 may form the base of the display panel 110. The base substrate 1120 may include a transparent or opaque material. In an embodiment, the base substrate 1120 may include glass, quartz, plastic, and the like. These may be used alone or in combination with each other. In other embodiments, the base substrate 1120 may include silicon (Si), a silicon wafer, and the like. These may be used alone or in combination with each other.

The first insulating layer 1122 may be disposed on the base substrate 1120. The first insulating layer 1122 may prevent metal atoms or impurities from diffusing from the base substrate 1120 to the active pattern 1144. In some aspects, the first insulating layer 1122 may control a heat supply rate during a crystallization process for forming the active pattern 1144. In an embodiment, the first insulating layer 1122 may include an inorganic insulating material. For example, the inorganic insulating material may include silicon oxide (SiOₓ), silicon nitride (SiNₓ), silicon oxynitride (SiOₓN_{y}), and the like.

The second insulating layer 1124 may be disposed on the first insulating layer 1122. The second insulating layer 1124 may improve the coupling between the first insulating layer 1122 and the active pattern 1144 and/or the coupling between conductive layers disposed between the first insulating layer 1122 and the second insulating layer 1124. In an embodiment, the second insulating layer 1124 may include an inorganic insulating material.

The active pattern 1144 may be disposed on the second insulating layer 1124. The active pattern 1144 may include a first conductive area connected to the first electrode 1140, a second conductive area connected to the second electrode 1146, and a channel area between the first conductive area and the second conductive area. The first conductive area may be referred to as a source area or a drain area. The second conductive area may be referred to as a drain area or a source area. In an embodiment, the active pattern 1144 may include amorphous silicon, polycrystalline silicon, oxide semiconductor, and the like. These may be used alone or in combination with each other.

The third insulating layer 1126 may be disposed on the active pattern 1144. In an embodiment, the third insulating layer 1126 may include an inorganic insulating material. In an embodiment, the third insulating layer 1126 may cover an upper surface of the active pattern 1144 along the profile of the active pattern 1144. However, the third insulating layer 1126 according to embodiments of the present disclosure may have a substantially flat upper surface without creating a step around the active pattern 1144.

The gate electrodes 1142 may be disposed on the third insulating layer 1126. The gate electrodes 1142 may overlap the active pattern 1144 in a plan view. For example, the channel area of the active pattern 1144 may be a portion of the active pattern 1144 that overlaps the gate electrode 1142. In an embodiment, the gate electrode 1142 may include a conductive material.

The fourth insulating layer 1128 may be disposed on the third insulating layer 1126. For example, the fourth insulating layer 1128 may cover the gate electrode 1142 on the third insulating layer 1126. In an embodiment, the fourth insulating layer 1128 may include an inorganic insulating material. In an embodiment, the fourth insulating layer 1128 may cover an upper surface of the gate electrode 1142 along the profile of the gate electrode 1142. However, the fourth insulating layer 1128 according to embodiments of the present disclosure may have a substantially flat upper surface without creating a step around the gate electrode 1142.

The first electrode 1140 and the second electrode 1146 may be disposed on the fourth insulating layer 1128. The first electrode 1140 and the second electrode 1146 may be electrically connected to the first conductive area and the second conductive area, respectively. For example, the first electrode 1140 and the second electrode 1146 may directly contact the first conductive area and the second conductive area through contact holes that penetrate the third insulating layer 1126 and the fourth insulating layer 1128 in a thickness direction (e.g., the third direction DR3). The first electrode 1140 may be referred to as a source electrode or a drain electrode. The second electrode 1146 may be referred to as a drain electrode or a source electrode.

The fifth insulating layer 1130 may be disposed on the fourth insulating layer 1128. For example, the fifth insulating layer 1130 may cover the first electrode 1140 and the second electrode 1146 on the fourth insulating layer 1128. In an embodiment, the fifth insulating layer 1130 may include an organic insulating material. For example, the organic insulating material may include polyimide, polyamide, polysulfone, and the like. These may be used alone or in combination with each other. In an embodiment, the fifth insulating layer 1130 may have a substantially flat upper surface.

The pixel electrode 1160 may be disposed on the fifth insulating layer 1130. The pixel electrode 1160 may contact or be electrically connected to the second electrode 1146 through a contact hole that penetrates the fifth insulating layer 1130 in a thickness direction (e.g., the third direction DR3). However, the pixel electrode 1160 according to embodiments of the present disclosure is not necessarily limited thereto, and the pixel electrode 1160 may contact or be electrically connected to the first electrode 1140.

In an embodiment, the pixel electrode 1160 may be a transmissive electrode, a semi-transmissive electrode, or a reflective electrode. For example, the pixel electrode 1160 may include silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), zinc (Zn), and the like. These may be used alone or in combination with each other.

The pixel defining layer 1132 may be disposed on the fifth insulating layer 1130. The pixel defining layer 1132 may partially cover the pixel electrode 1160. For example, the pixel defining layer 1132 may define a hole extending to (or exposing) a central portion of the pixel electrode 1160, and the pixel defining layer 1132 may cover an edge portion of the pixel electrode 1160. In an embodiment, the pixel defining layer 1132 may include an organic insulating material.

The light-emitting layer 1162 may be disposed on the pixel electrode 1160. For example, the light-emitting layer 1162 may be disposed on the pixel electrode exposed by the hole of the pixel defining layer 1132. In an embodiment, the light-emitting layer 1162 may include a light-emitting material. For example, the light-emitting material may include an organic light-emitting material, a quantum dot, and the like. These may be used alone or in combination with each other.

The common electrode 1164 may be disposed on the pixel defining layer 1132. In an embodiment, the common electrode 1164 may include a conductive material. For example, the common electrode 1164 may include aluminum (Al), platinum (Pt), silver (Ag), magnesium (Mg), gold (Au), chromium (Cr), tungsten (W), titanium (Ti), and the like. These may be used alone or in combination with each other.

The thin film encapsulation layer 120 may be disposed on the display panel 110. The thin film encapsulation layer 120 may prevent moisture or foreign substances from entering the display panel 110. The first encapsulation layer 1220 may be disposed on the common electrode 1164. The first encapsulation layer 1220 may have a substantially uniform thickness along the profile of the common electrode 1164. In an embodiment, the first encapsulation layer 1220 may include an inorganic insulating material. The second encapsulation layer 1240 may be disposed on the first encapsulation layer 1220. The second encapsulation layer 1240 may have a substantially flat upper surface without creating a step around the first encapsulation layer 1220. The second encapsulation layer 1240 may include an organic insulating material such as polyimide, polyacrylate, and the like. The third encapsulation layer 1260 may be disposed on the second encapsulation layer 1240. The third encapsulation layer 1260 may have a substantially uniform thickness and a substantially flat upper surface. The third encapsulation layer 1260 may include an inorganic insulating material.

The lens layer 130 may be disposed on the thin film encapsulation layer 120. The lens layer 130 may control or modulate characteristics of the light (e.g., characteristics such as light collection, diffusion, scattering, polarization, and the like) emitted from the light-emitting element 116. Accordingly, the light output quality of the display panel 110 may be improved. The lens layer 130 may be referred to as a micro lens, a micro lens array, and the like.

The lens substrate 1320 may form the base of the lens layer 130. In an embodiment, the lens substrate 1320 may include glass, plastic, and the like. For example, the lens substrate 1320 may include a photosensitive polyimide (PSPI). In an embodiment, the lens substrate 1320 may be a transparent substrate.

The refractive layer 1340 may be disposed on the lens substrate 1320. The refractive layer 1340 may have a relatively high refractive index. For example, the refractive layer 1340 may include silicon (Si), silicon oxide (SiOₓ), tin oxide (SnOₓ), titanium oxide (TiOₓ), titanium-tin oxide (TiOₓ-SiO_{y}), zirconia oxide (ZrOₓ), aluminum oxide (AlₓO_{y}), hafnium oxide (HfOₓ), indium oxide (InₓO_{y}), indium tin oxide (ITO), nitride, polyethylene resin, polyacrylic resin, polyvinyl chloride (PVC) resin, polyvinylpyrrolidone (PVP), polyimide resin, polystyrene resin, epoxy resin, and the like. These may be used alone or in combination with each other.

The refractive layer 1340 may have a groove pattern GP in the display area DA. For example, a portion of the refractive layer 1340 in the display area DA may have a pattern that is depressed toward the thin film encapsulation layer 120. In an embodiment, the groove pattern GP of the refractive layer 1340 may have a rounded shape in a direction toward the lens substrate 1320. For example, in a cross-section, the groove pattern GP may have a rounded shape in a direction opposite the third direction DR3 (e.g., a direction away from the lens substrate 1320). Accordingly, the characteristics of the light (e.g., characteristics such as light collection, diffusion, scattering, polarization, and the like) emitted from the light-emitting element 116 may be controlled or modulated through the groove pattern GP of the refractive layer 1340.

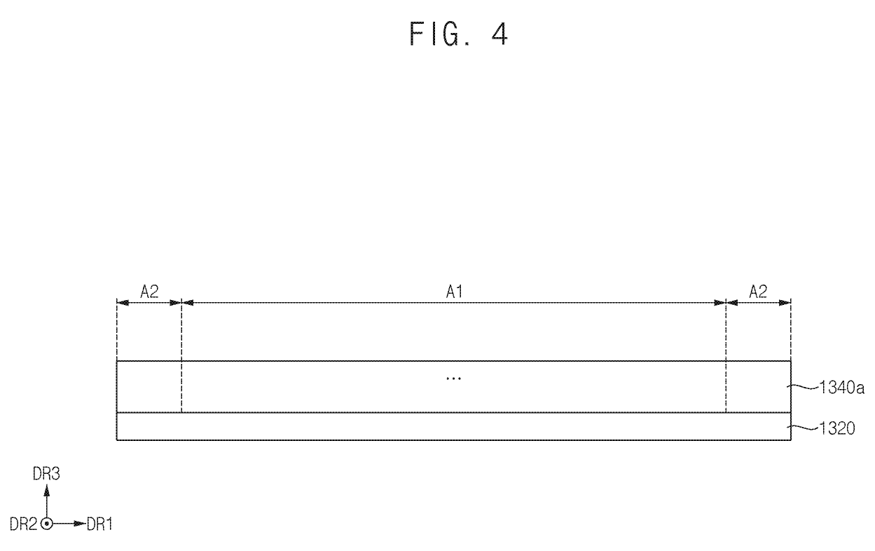

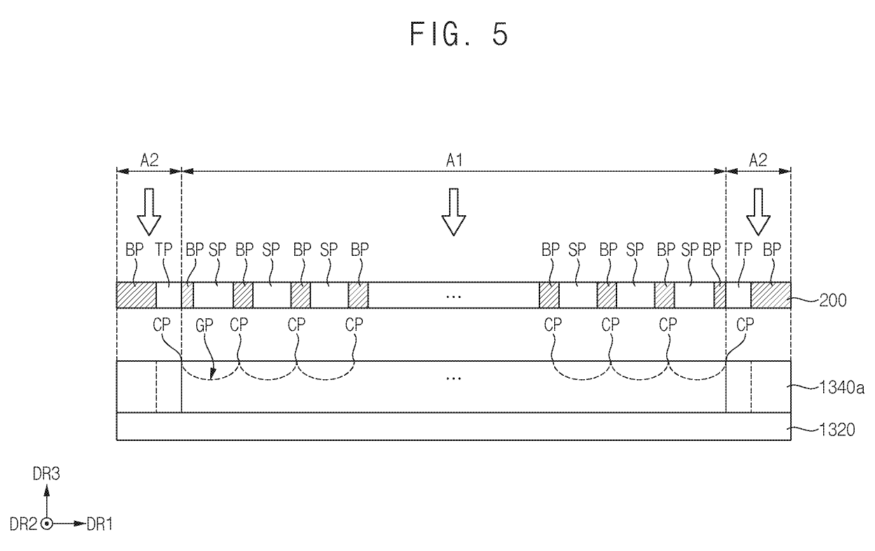

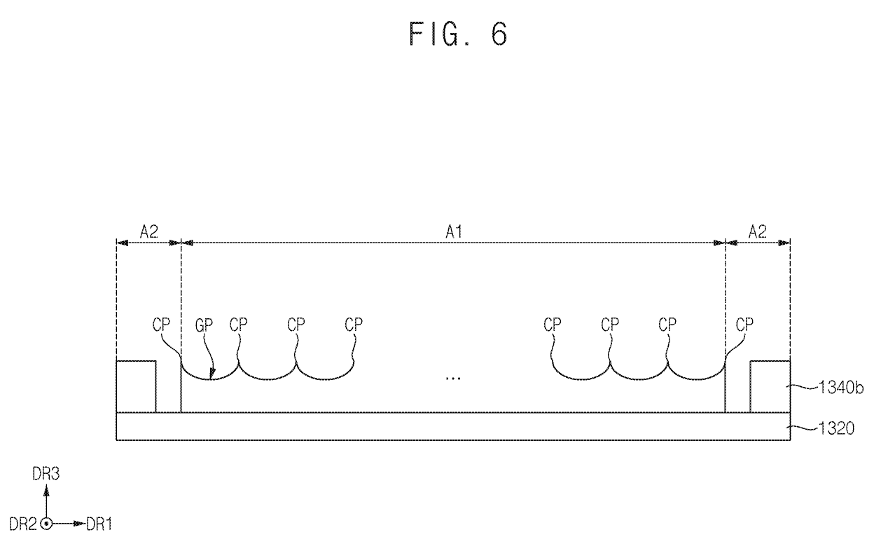

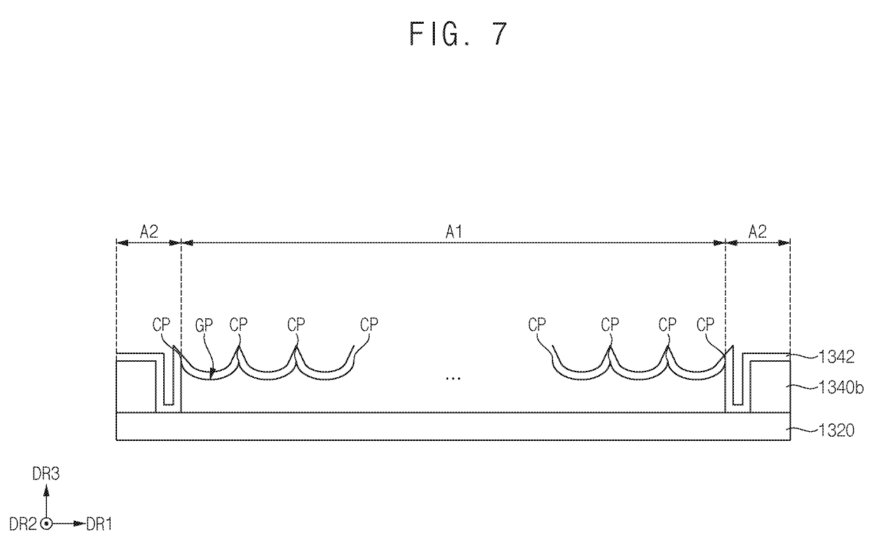

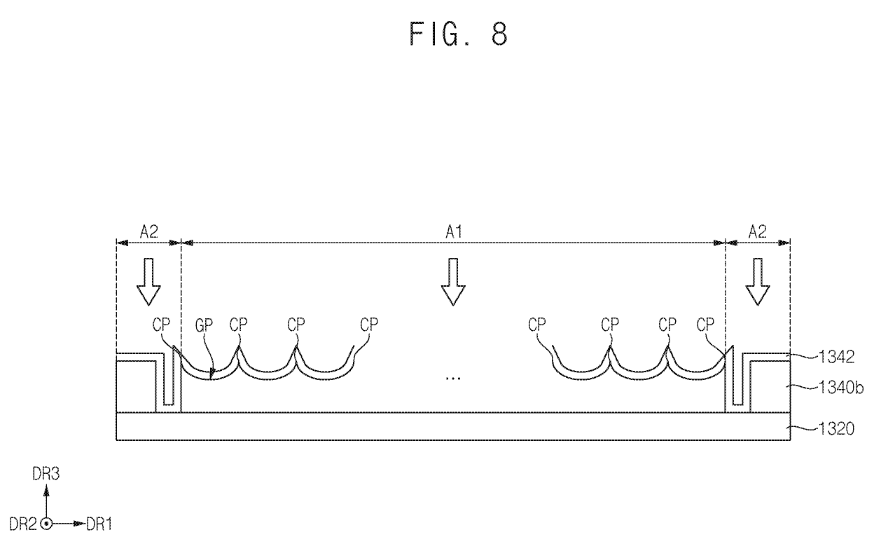

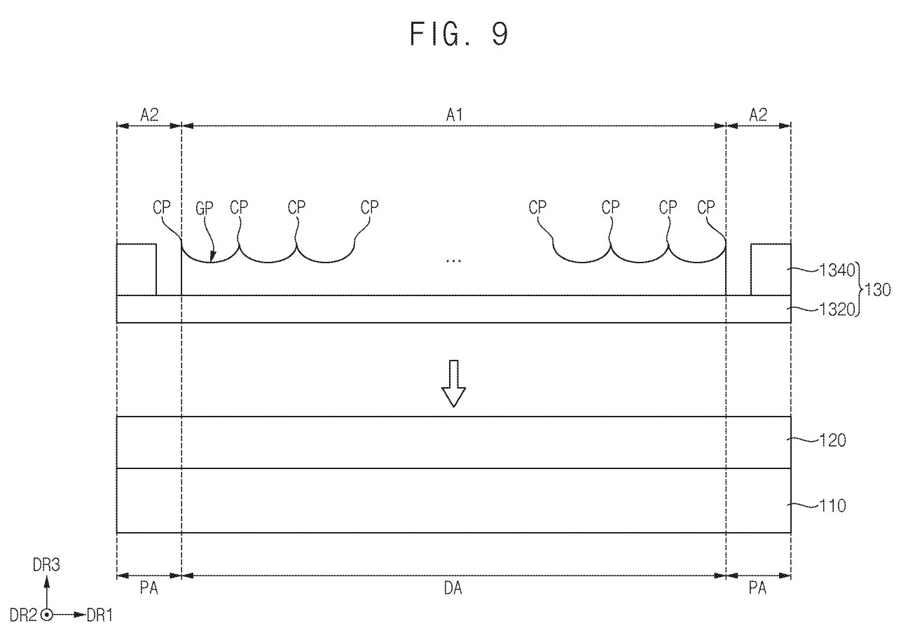

A metal particle may be formed on a surface PS of the refractive layer 1340. For example, the metal particle may include indium (In), titanium (Ti), and the like. The metal particle formed on the surface PS of the refractive layer 1340 may be a component included in a fixing film (e.g., a fixing film 1342 of FIG. 7) deposited on the surface PS of the refractive layer 1340 to maintain the shape of the refractive layer 1340. This will be described herein with reference to FIGS. 4, 5, 6, 7, 8, and 9.

An opening OP may be formed in the refractive layer 1340 in the peripheral area PA. In an embodiment, the opening OP may not overlap the pixel (PX, refer to FIG. 1) in a plan view. In an embodiment, the opening OP may have a shape surrounding at least a portion of the display area DA. A portion of the refractive layer 1340 in the peripheral area PA may have a substantially flat upper surface. In other words, the portion of the refractive layer 1340 in the peripheral area PA may not have the groove pattern GP.

The opening OP may extend to (or expose) a surface of the lens substrate 1320. Moisture or gas generated during the manufacturing process of the lens layer 130 may be released to the outside through the opening OP. For example, the lens substrate 1320 including photosensitive polyimide (PSPI) may release gas during the manufacturing process of the lens layer 130, and the gas may weaken the bonding force between the lens substrate 1320 and the refractive layer 1340 when the gas remain within the lens layer 130. Accordingly, since the opening OP formed in the refractive layer 1340 in the peripheral area PA releases the gas, a lifting phenomenon caused by weakening the bonding force between the lens substrate 1320 and the refractive layer 1340 may be prevented. Accordingly, the durability of the display device 100 including the lens layer 130 may be improved, and the display quality may be improved because a phenomenon of deterioration of the resolution of the image generated by the light emitted from the light-emitting element 116 is prevented.

The overcoating layer 136 may be disposed on the refractive layer 1340. In an embodiment, the overcoating layer 136 may fill the groove pattern GP and provide a substantially flat upper surface. In an embodiment, the overcoating layer 136 may include an acrylic resin, an epoxy resin, a phenolic resin, a polyamide resin, a polyimide resin, and the like. These may be used alone or in combination with each other.

The optical functional layer 140 may be disposed on the lens layer 130. In an embodiment, the optical functional layer 140 may be a color filter or a polarization plate that selectively transmits light emitted from the light-emitting element 116. However, the optical functional layer 140 according to embodiments of the present disclosure is not necessarily limited thereto.

The encapsulation substrate 150 may be disposed on the optical functional layer 140. In an embodiment, the encapsulation substrate 150 may include glass, quartz, plastic, and the like. These may be used alone or in combination with each other. In an embodiment, at least a portion of the encapsulation substrate 150 may be transparent.

FIGS. 4, 5, 6, 7, 8, and 9, are views illustrating a method of manufacturing the display device of FIG. 2.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Hereinafter, redundant descriptions with the descriptions above with reference to FIGS. 1-3 may be omitted or summarized.

Referring to FIGS. 4, 5, 6, 7, 8, and 9, the method may include forming a first preliminary refractive layer 1340a on the lens substrate 1320. For example, the first preliminary refractive layer 1340a may be formed across a first area A1 and a second area A2. The first area A1 may correspond to the display area DA of the display device 100 of FIG. 1. In some aspects, the second area A2 may correspond to the peripheral area PA of the display device 100 of FIG. 1.

The method may include performing an exposure process on the first preliminary refractive layer 1340a using a mask 200. In an embodiment, the mask 200 may be a halftone mask or a binary mask. However, the type and number of the mask 200 according to embodiments of the present disclosure are not necessarily limited thereto, and a plurality of different masks may be used in the first area A1 and the second area A2 during the exposure process.

The mask 200 may include a light blocking portion BP, a transmission portion TP, and a semi-transmission portion SP. The light blocking portion BP may block light passing through the mask 200. In some aspects, the transmission portion TP may transmit light passing through the mask 200. In some aspects, the semi-transmission portion SP may have a transmittance that is smaller than a transmittance of the transmission portion TP and greater than a transmittance of the light blocking portion BP.

In an embodiment, the light blocking portion BP and the semi-transmission portion SP of the mask 200 may be repeatedly arranged in the first area A1. In an embodiment, the transmission portion TP and the light blocking portion BP of the mask 200 may be positioned in the second area A2.

After the mask 200 is disposed on the first preliminary refractive layer 1340a, the method may include removing a portion of the first preliminary refractive layer 1340a through performing the exposure process, thereby forming a second preliminary refractive layer 1340b. In the first area A1, a protrusion CP having a maximum height may be formed at a portion of the first preliminary refractive layer 1340a overlapping the light blocking portion BP. In some aspects, in the first area A1, a groove pattern GP may be formed by removing the first preliminary refractive layer 1340a at a portion overlapping the semi-transmission portion SP and around the semi-transmission portion SP. Accordingly, in the first area A1, the second preliminary refractive layer 1340b may have the groove pattern GP and the protrusion CP that are repeatedly arranged.

In the second area A2, a portion of the first preliminary refractive layer 1340a overlapping the transmission portion TP may be completely removed. Accordingly, an opening OP extending toward (or exposing) an upper surface of the lens substrate 1320 may be formed in the second area A2 of the second preliminary refractive layer 1340b. In an embodiment, the groove pattern GP and the opening OP may be simultaneously formed.

After the second preliminary refractive layer 1340b is formed, the method may include forming (e.g., depositing) a fixing film 1342 on the second preliminary refractive layer 1340b. In an embodiment, the fixing film 1342 may have a substantially uniform thickness and may be formed on the second preliminary refractive layer 1340b across the first area A1 and the second area A2. For example, the fixing film 1342 may have a pattern substantially identical to the groove pattern GP in the first area A1. In some aspects, the fixing film 1342 may fill the opening OP and cover the exposed upper surface of the lens substrate 1320 in the second area A2.

In an embodiment, the fixing film 1342 may include a transparent conductive oxide (TCO). For example, the fixing film 1342 may include indium tin oxide (ITO), indium zinc oxide (IZO), indium gallium zinc oxide (IGZO), and the like. These may be used alone or in combination with each other. In an embodiment, the fixing film 1342 may include a conductive layer including a metal such as titanium (Ti).

After the fixing film 1342 is formed on the second preliminary refractive layer 1340b, the method may include performing a curing process on the second preliminary refractive layer 1340b. For example, the curing process may be an ultraviolet (UV) curing process. However, the type of the curing process of the present disclosure is not necessarily limited thereto. Since the curing process is performed on the second preliminary refractive layer 1340b after the fixing film 1342 is formed on the second preliminary refractive layer 1340b, the shape of the second preliminary refractive layer 1340b may not be deformed, and the fixation of the second preliminary refractive layer 1340b may be continuously maintained.

After the curing process is performed, the method may include removing the fixing film 1342 formed on the second preliminary refractive layer 1340b. In an embodiment, the fixing film 1342 may be removed through an etching process. For example, the etching process may be a wet etch or a dry etch. The removal of the fixing film 1342 from the second preliminary refractive layer 1340b may form the refractive layer 1340. Since a material included in the fixing film 1342 remains on the surface (the surface PS of FIG. 2) of the refractive layer 1340, a metal particle may form on the surface of the refractive layer 1340. The metal particle may include indium (In), titanium (Ti) and the like. However, the type of the metal particle according to embodiments of the present disclosure is not necessarily limited thereto.

After the refractive layer 1340 is formed, the method may include bonding the lens layer 130 including the lens substrate 1320 and the refractive layer 1340 to the thin film encapsulation layer 120. For example, the lens layer 130 may be bonded to the thin film encapsulation layer 120 with the lens substrate 1320 facing the thin film encapsulation layer 120. After the optical functional layer 140 and the encapsulation substrate 150 of FIG. 2 are formed on the lens layer 130, the display device 100 of FIG. 1 may be manufactured.

As described herein, in the method of manufacturing the display device 100 according to embodiments of the present disclosure, since a curing process is performed on the second preliminary refractive layer 1340b after the fixing film 1342 is formed on the second preliminary refractive layer 1340b, the shape of the second preliminary refractive layer 1340b may not be deformed, and the fixation of the second preliminary refractive layer 1340b may be continuously maintained. Accordingly, the method may be implemented without an additional process for fixing and maintaining the shape of the refractive layer 1340, and the process time and the process cost may be reduced. Since secondary etching is not performed on the refractive layer 1340 through the dry etching process using photoresist, defect generation due to etching in the refractive layer 1340 may be reduced, and a display device 100 with improved durability may be easily manufactured.

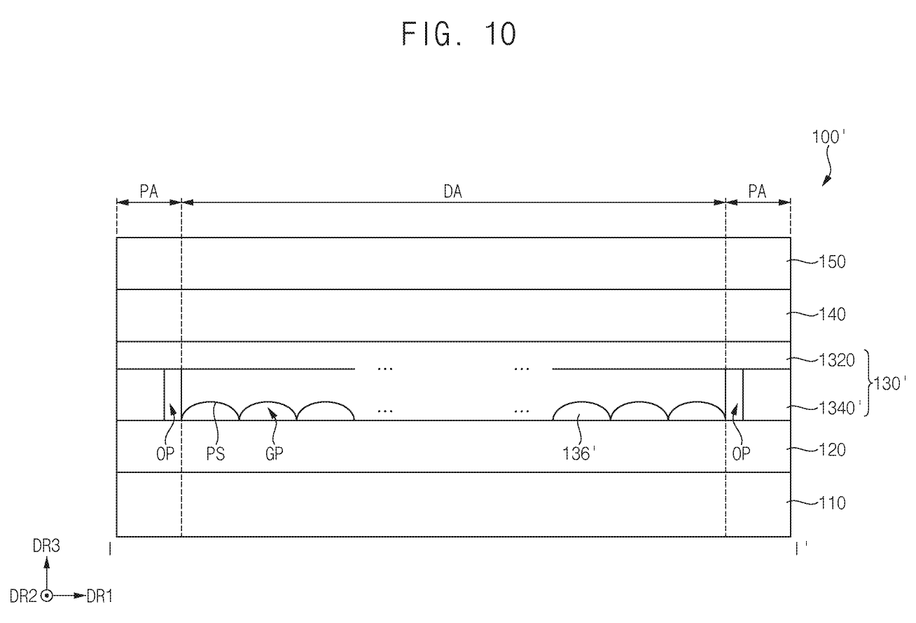

FIG. 10 is a cross-sectional view illustrating another example of a cross-section of the display device taken along the line I-I’ of FIG. 1.

The display device 100’ described with reference to FIG. 10 may be substantially the same or similar to the display device 100 described with reference to FIG. 2, except that the structure of a lens layer 130’ is different. Hereinafter, redundant descriptions of the display device 100 described with reference to FIG. 2 may be omitted or summarized.

Referring to FIG. 10, the display device 100’ may include an adhesive layer 136’. The lens layer 130’ may include a lens substrate 1320 and a refractive layer 1340’. The refractive layer 1340’ may be disposed on a thin film encapsulation layer 120. In some aspects, the lens substrate 1320 may be disposed on the refractive layer 1340’. In an embodiment, in a cross-section, the refractive layer 1340’ may be disposed between the thin film encapsulation layer 120 and the lens substrate 1320. In an embodiment, a groove pattern GP may have a rounded shape in a direction toward the lens substrate 1320. For example, the groove pattern GP may have a rounded shape toward the third direction DR3. In other words, the refractive layer 1340’ of FIG. 10 may be symmetrical with the refractive layer 1340 of FIG. 1 with respect to a plane perpendicular to the third direction DR3.

The adhesive layer 136’ may be disposed between the refractive layer 1340 and the thin film encapsulation layer 120 in a cross-section. The adhesive layer 136’ may bond the refractive layer 1340 and the thin film encapsulation layer 120. In an embodiment, the adhesive layer 136’ may include an optically clear adhesive (OCA), an acrylic-based adhesive, and the like. These may be used alone or in combination with each other.

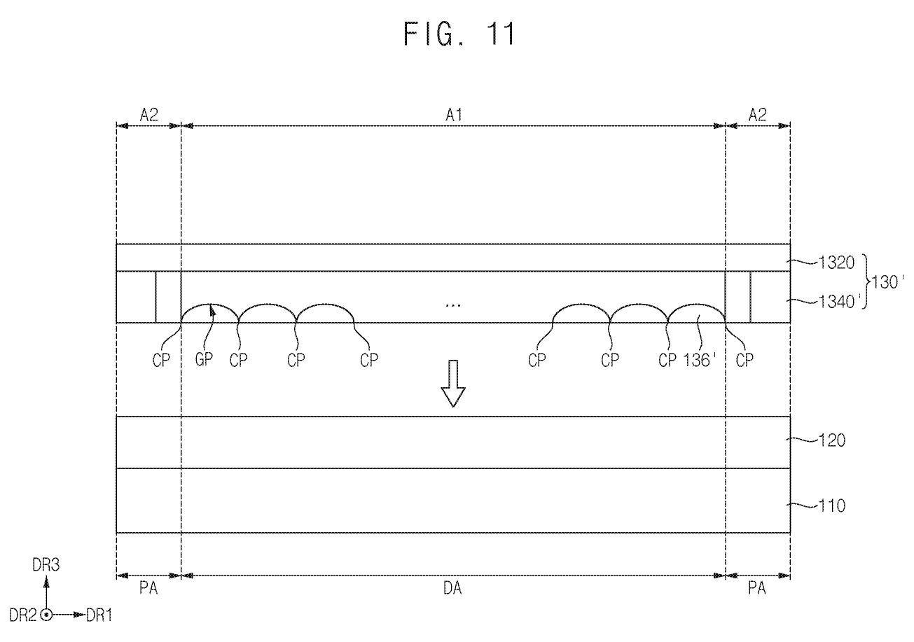

FIG. 11 is a view illustrating a method of manufacturing the display device of FIG. 10.

The method of manufacturing the display device 100’ described with reference to FIG. 11 may be substantially the same as the method of manufacturing the display device 100 described with reference to FIGS. 4-9, except for the process of forming the lens layer 130’ on the thin film encapsulation layer 120. Hereinafter, redundant descriptions of the method of manufacturing the display device 100 described with reference to FIGS. 4-9 may be omitted or summarized.

Referring to FIG. 11, before the lens layer 130’ and the thin film encapsulation layer 120 are bonded to each other, the adhesive layer 136’ may be formed in the groove pattern GP of the refractive layer 1340’. For example, the adhesive layer 136’ may fill a recessed portion positioned between the protrusions CP of the refractive layer 1340’ and form a substantially flat surface. After the adhesive layer 136’ is formed on the refractive layer 1340’, the lens layer 130’ and the thin film encapsulation layer 120 may be bonded to each other such that the refractive layer 1340’ of the lens layer 130’ faces the thin film encapsulation layer 120. After the optical functional layer 140 and the encapsulation substrate 150 of FIG. 10 are formed on the lens layer 130’, the display device 100’ of FIG. 10 may be manufactured.

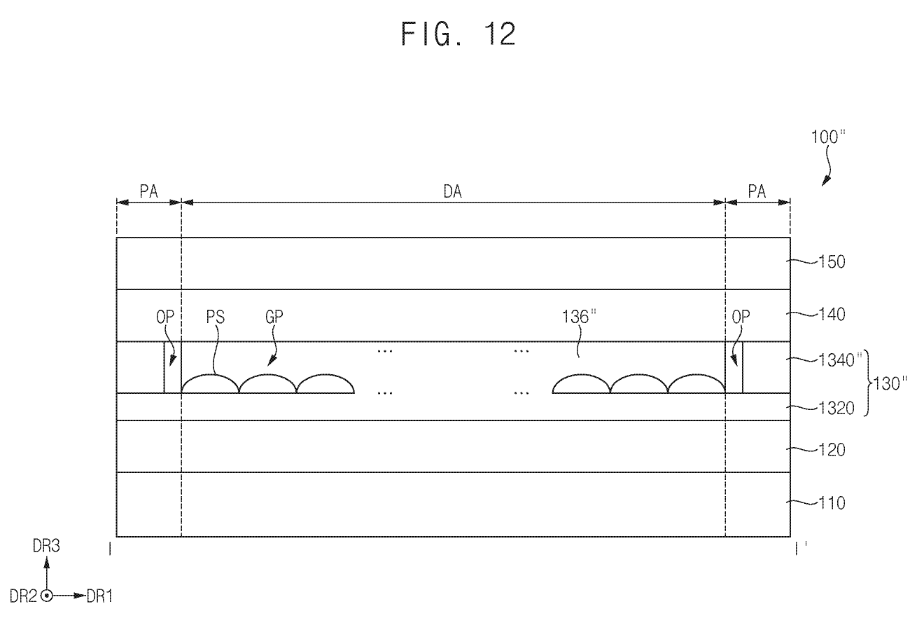

FIG. 12 is a cross-sectional view illustrating still another example of a cross-section of the display device taken along the line I-I’ of FIG. 1.

A display device 100’’ described with reference to FIG. 12 may be substantially the same or similar to the display device 100 described with reference to FIG. 2, except that the structure of a lens layer 130’’ is different. Hereinafter, redundant descriptions of the display device 100 described with reference to FIG. 2 may be omitted or summarized.

Referring to FIG. 12, the display device 100’’ may include a lens layer 130’’ and an overcoating layer 136’’. The lens layer 130’’ may include a lens substrate 1320 and a refractive layer 1340’’. The lens substrate 1320 may be disposed on the thin film encapsulation layer 120. The refractive layer 1340’’ may be disposed on the lens substrate 1320. In other words, the lens substrate 1320 may be disposed between the thin film encapsulation layer 120 and the refractive layer 1340’’ in a cross-section.

In an embodiment, a groove pattern GP of the refractive layer 1340’’ may have a rounded shape in an opposite direction of a direction toward the lens substrate 1320. For example, the groove pattern GP may have a rounded or convex shape toward the third direction DR3 in a cross-section. In other words, the refractive layer 1340’’ of FIG. 12 may be symmetrical with the refractive layer 1340 of FIG. 2 with respect to a plane perpendicular to the third direction DR3. In some aspects, the shape of the overcoating layer 136’’ of FIG. 12 may be different from the overcoating layer 136 of FIG. 2 depending on the shape of the refractive layer 1340’’.

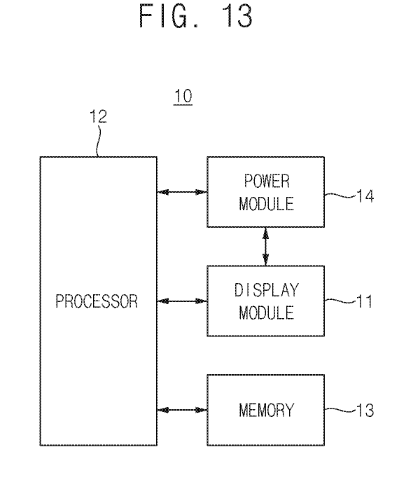

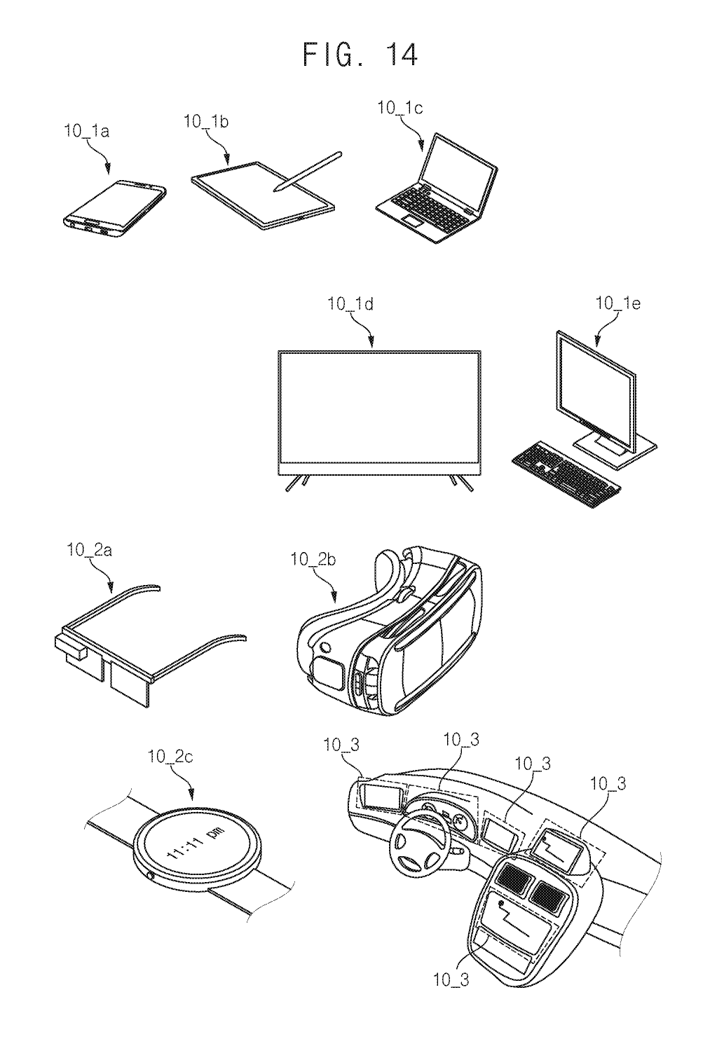

FIG. 13 is a block diagram of an electronic device according to an embodiment of the present disclosure. FIG. 14 is a schematic view illustrating various embodiments of the electronic device of FIG. 13.

Referring to FIG. 13, an electronic device 10 according to an embodiment may include a display module 11, a processor 12, a memory 13, and a power module 14. The display device according to an embodiment (e.g., the display devices 100, 100’, and 100’’ of FIGS. 1, 10, and 12) may be applied to a variety of electronic devices. The electronic device 10 according to an embodiment may include the display device described herein, and may further include modules or devices having other additional functions in addition to the display device.

The processor 12 may include at least one of a central processing unit (CPU), an application processor (AP), a graphic processing unit (GPU), a communication processor (CP), an image signal processor (ISP), and a controller.

The memory 13 may store data information for operation of the processor 12 or the display module 11. When the processor 12 executes an application stored in the memory 13, an image data signal and/or an input control signal may be transmitted to the display module 11, and the display module 11 may process the received signals and may output image information through a display screen. For example, the processor 12 may transmit the image data signal and the input control signal to the display panel 110 of FIG. 2.

The power module 14 may include a power supply module, such as a power adapter, a battery device, or the like, and a power conversion module that converts power supplied by the power supply module to generate the power for operation of the electronic device 10.

At least one of the components of the electronic device 10 described herein may be included in the display device according to the embodiments described herein. In some aspects, some of the individual modules that are functionally included in one module may be included in the display device and others may be provided separately from the display device. For example, the display device may include the display module 11, and the processor 12, the memory 13, and the power module 14 may be provided in the form of other devices in the electronic device 10 other than the display device.

Referring to FIG. 14, various electronic devices to which a display device according to the embodiments is applied may include image display electronic devices such as a smartphones 10_1a, a tablet PC 10_1b, a laptop 10_1c, a television 10_1d, a desk monitor 10_1e, or the like, wearable electronic devices including display modules such as a smart glasses 10_2a, a head-mounted display 10_2b, and a smart watch 10_2c, or the like, and vehicle electronic devices 10_3 including display modules such as a CID (center information display) which may be disposed on a instrument panel, a center fascia, and a dashboard of an automobile and a room mirror display, or the like.

As described herein, the electronic device 10 according to embodiments of the present disclosure may include a display device with improved durability and display quality, the processor 12, the power module 14, and other components for operating the display device, such that the electronic device 10 may provide an image to a user while operating stably.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although example embodiments have been described with reference to the figures, those skilled in the art will readily appreciate that many variations and modifications may be made therein without departing from the spirit and scope of the present disclosure as defined in the appended claims.

What is claimed is:

1. A display device comprising:
a display panel comprising:
a display area;
a peripheral area adjacent to the display area; and
a pixel which emits light; and
a lens layer which is on the display panel and controls the light emitted from the pixel, wherein the lens layer comprises:
a lens substrate positioned across the display area and the peripheral area; and
a refractive layer which has a groove pattern in the display area and defines an opening extending toward a surface of the lens substrate in the peripheral area.

2. The display device of claim 1, further comprising a metal particle formed on a surface of the refractive layer.

3. The display device of claim 2, wherein the metal particle comprises at least one of indium or titanium.

4. The display device of claim 1, wherein the groove pattern has a rounded shape in a direction toward the lens substrate in a cross-section.

5. The display device of claim 1, wherein the groove pattern has a rounded shape in a direction away from the lens substrate in a cross-section.

6. The display device of claim 1, wherein the lens substrate is between the refractive layer and the display panel in a cross-section.

7. The display device of claim 6, further comprising:
an overcoating layer on the lens substrate.

8. The display device of claim 1, wherein the refractive layer is between the lens substrate and the display panel in a cross-section.

9. The display device of claim 8, further comprising:
an adhesive layer which fills the groove pattern of the refractive layer and is between the display panel and the refractive layer in the cross-section.

10. The display device of claim 1, wherein the lens substrate comprises a photosensitive polyimide.

11. A method of manufacturing a display device, the method comprising:
forming a first preliminary refractive layer on a lens substrate, wherein the lens substrate comprises a first area and a second area adjacent to the first area;
forming a second preliminary refractive layer which has a groove pattern in the first area and defines an opening extending toward a surface of the lens substrate in the second area by removing a portion of the first preliminary refractive layer;
forming a fixing film on the second preliminary refractive layer in the first area and the second area;
curing the second preliminary refractive layer;
forming a refractive layer by removing the fixing film in the first area and the second area; and
bonding the lens substrate and the refractive layer to a display panel.

12. The method of claim 11, wherein forming the second preliminary refractive layer comprises:
providing a mask comprising a light blocking portion, a transmission portion, and a semi-transmission portion which has a transmittance greater than a transmittance of the light blocking portion and smaller than a transmittance of the transmission portion;
forming the opening by removing a first portion of the second preliminary refractive layer corresponding to the transmission portion of the mask; and
forming the groove pattern by removing a second portion of the second preliminary refractive layer corresponding to the light blocking portion and the semi-transmission portion of the mask, wherein the second portion is different from the first portion.

13. The method of claim 11, wherein the fixing film comprises at least one selected from a group consisting of indium tin oxide (ITO), indium zinc oxide (IZO), indium gallium zinc oxide (IGZO), and titanium.

14. The method of claim 11, wherein in the bonding the lens substrate and the refractive layer to the display panel,
the lens substrate and the refractive layer are bonded to the display panel such that the lens substrate faces the display panel.

15. The method of claim 11, wherein in the bonding the lens substrate and the refractive layer to the display panel,
the lens substrate and the refractive layer are bonded to the display panel such that the refractive layer faces the display panel.

16. The method of claim 11, wherein in the bonding the lens substrate and the refractive layer to the display panel,
the display panel comprises a display area and a peripheral area adjacent to the display area,
the display area of the display panel and the first area of the lens substrate correspond to each other, and
the peripheral area of the display panel and the second area of the lens substrate correspond to each other.

17. An electronic device comprising:
a display panel comprising:
a display area;
a peripheral area adjacent to the display area; and
a pixel which emits light;
a lens layer which is on the display panel and controls the light emitted from the pixel, wherein the lens layer comprises:
a lens substrate positioned across the display area and the peripheral area; and
a refractive layer which has a groove pattern in the display area and defines an opening extending toward a surface of the lens substrate in the peripheral area; and
a processor which transmits an image data signal and an input control signal to the display panel.

18. The electronic device of claim 17, further comprising a metal particle formed on a surface of the refractive layer.

19. The electronic device of claim 18, wherein the metal particle comprises at least one of indium or titanium.

20. The electronic device of claim 17, wherein the lens substrate comprises a photosensitive polyimide.
